(19) United States
(12) Patent Application Publication
(10) Pub. No.: US 2025/0148481 A1
(43) Pub. Date: May 8, 2025

(54) METHOD FOR ACHIEVING CARBON NEUTRALITY BASED ON ESG IN INDUSTRIAL SITES AND APPARATUS THEREOF

(71) Applicant: AJOU UNIVERSITY INDUSTRY-ACADEMIC COOPERATION FOUNDATION, Suwon-si (KR)

(72) Inventors: Bong Sik OH, Suwon-si (KR); SangChul PARK, Yongin-si (KR)

(73) Assignee: AJOU UNIVERSITY INDUSTRY-ACADEMIC COOPERATION FOUNDATION, Suwon-si (KR)

(21) Appl. No.: 18/901,173

(22) Filed: Sep. 30, 2024

(30) Foreign Application Priority Data
Nov. 3, 2023 (KR) 10-2023-0151103

(51) Int. Cl. G06Q 30/018

(52) U.S. Cl. CPC G06Q 30/018

(57) ABSTRACT

The present disclosure relates to a technology for achieving carbon neutrality in ESG-based industrial sites. An apparatus for achieving carbon neutrality analyzes energy performance of factories, industrial facilities, and plants, derives energy saving factors and renewable energy production factors, verifies performance of facility materials and facility construction methods to comply with GRI standards, for example, optimizes internal air in accordance with the GRI standards, and quantitatively measures and evaluates environmental, social, and governance (ESG) achievement rates of factories, the industrial facilities, and the plants.

### CROSS-REFERENCE TO RELATED APPLICATION

This application claims the benefit of Korea Patent Application No. 10-2023-0151103, filed on 3 Nov. 2023, which is incorporated herein by reference for all purposes as if fully set forth herein.

### TECHNICAL FIELD

The present disclosure relates to a method and an apparatus for achieving carbon neutrality in ESG-based industrial sites, and more specifically, relates to an ESG carbon neutral platform that can provide carbon reduction solutions by configuring and proposing a systematic, rational, and reliable FEMS for establishing carbon-neutral, eco-friendly industrial sites.

### BACKGROUND

Abnormal signs and damages caused by climate change have appeared all over the world. Countermeasures against a climate crisis have become urgent issues which can no longer be avoided and are directly related to survival. Each country in the world has recognized the severity of the climate crisis, and has progressively established a national policy direction toward carbon neutrality. Carbon neutrality means a state where actual carbon emissions become net-zero by absorbing and removing greenhouse gases emitted into the atmosphere, and the international community has prepared specific and long-term plans to achieve carbon neutrality.

Particularly, in order to achieve this purpose, policies and legal standards for achieving the carbon neutrality in most critical industrial construction sectors have been established, and a lot of research and effort have been made. However, there is a lack of basic data to support the carbon neutrality, and there is no systematic and reliable methodology.

In addition, industrial management using networks is generally limited to some sectors, and as a result, overall management of industrial facilities has not been achieved, and thus, manpower and costs have been wasted in comprehensive system management of industrial facilities.

In particular, it is most important to provide professional and reliable total solutions that suggest methods for achieving the carbon neutrality in design and construction sites and that fulfill performance verification and evaluation, and a demand for a professional carbon neutral platform that plans and implements an integrated and systematic carbon neutral strategy has become a major social issue.

### SUMMARY

A technical aspect to be achieved by embodiments of the present specification is to provide an integrated and systematic carbon neutral strategy in an initial stage of establishing an industrial site which aims to achieve carbon neutrality. In order to achieve this aspect, an optimal energy self-sufficiency rate needs to be secured by reducing an energy demand and primary energy consumption in the industrial sites, based on energy saving techniques of passive design technology elements and active system technology elements through quantitative data analysis. In addition, the present disclosure aims to provide an ESG-based carbon neutral platform that verifies and evaluates total energy management and performance for rational decision-making such as material selection and construction technique suggestions, an indoor air optimization system for building a pleasant industrial environment, and a factory energy management system (FEMS) in order to construct a most realistic and sustainable industrial site that reduces carbon emissions, based on quantitative data.

According to an embodiment of the present disclosure, there is provided a method for achieving carbon neutrality. The method includes analyzing energy performance of factories, industrial facilities, and plants, deriving energy saving factors and renewable energy production factors, verifying performance of facility materials and facility construction methods, optimizing internal air, and quantitatively measuring and evaluating environmental, social, and governance (ESG) achievement rates for the factories, the industrial facilities, and the plants. In addition, deriving the energy saving factors and the renewable energy production factors may include performing energy modeling by reflecting information including at least one or a combination of shape information, weather information, insulation and heat generation information, facility information, facility efficiency information, and facility operation information of the factories, the industrial facilities, and the plants, and analyzing at least one or a combination of energy consumption, carbon emissions, and heat circulation of the factories, the industrial facilities, and the plants, through energy simulation. In addition, deriving the energy saving factors and the renewable energy production factors may include deriving passive technology elements or active technology elements which are energy-saving elements, through machine learning-based energy optimization models and data mining. In addition, optimizing the internal air may include constructing and providing a factory energy management system (FEMS) for energy optimization by reflecting results of analyzing the energy performance of the factories, industrial facilities, and the plants. In addition, optimizing the internal air may include controlling an Internet-of-Things (IoT)-based ventilation device through a test bed to which the facility materials and the facility construction methods are applied, and performing a simulation for optimizing indoor air by collecting information from an IoT-based sensor installed in the test bed, and providing settings for an IoT-based ventilation system that optimizes the indoor air in a prescribed space, based on results of the simulation. In addition, quantitatively measuring and evaluating the ESG achievement rates may include calculating a carbon reduction amount by applying a carbon emission factor, based on data collected from a FEMS or a ventilation system installed in the factories, the industrial facilities, and the plants, and evaluating ESG evaluation indicators for greenhouse gas emissions, an energy usage amount, a renewable energy usage ratio, a waste discharge amount, a water usage amount, air pollutant emissions, indoor fine dust concentration, and the amount of generated indoor air pollutants.

According to another embodiment of the present disclosure, there is provided an apparatus for achieving carbon neutrality. The apparatus includes a processor, and a memory in which one or more instructions executed by the processor are stored. The one or more instructions include analyzing energy performance of factories, industrial facilities, and plants, deriving energy saving factors and renewable energy production factors, verifying performance of facility materials and facility construction methods, optimizing internal air, and quantitatively measuring and evaluating environmental, social, and governance (ESG) achievement rates for the factories, the industrial facilities, and the plants. In addition, deriving the energy saving factors and the renewable energy production factors may include performing energy modeling by reflecting information including at least one or a combination of shape information, weather information, insulation and heat generation information, facility information, facility efficiency information, and facility operation information of the factories, the industrial facilities, and the plants, and analyzing at least one or a combination of energy consumption, carbon emissions, and heat circulation of the factories, the industrial facilities, and the plants, through energy simulation. In addition, deriving the energy saving factors and the renewable energy production factors may include deriving passive technology elements or active technology elements which are energy-saving elements, through machine learning-based energy optimization models and data mining. In addition, optimizing the internal air may include constructing and providing a factory energy management system (FEMS) for energy optimization by reflecting results of analyzing the energy performance of the factories, industrial facilities, and the plants. In addition, optimizing the internal air may include controlling an IoT-based ventilation device through a test bed to which the facility materials and the facility construction methods are applied, and performing a simulation for optimizing indoor air by collecting information from an IoT-based sensor installed in the test bed, and providing settings for an IoT-based ventilation system that optimizes the indoor air in a prescribed space, based on results of the simulation. In addition, quantitatively measuring and evaluating the ESG achievement rates may include calculating a carbon reduction amount by applying a carbon emission factor, based on data collected from a FEMS or a ventilation system installed in the factories, the industrial facilities, and the plants, and evaluating ESG evaluation indicators for greenhouse gas emissions, an energy usage amount, a renewable energy usage ratio, waste emissions, water usage amount, air pollutant emissions, indoor fine dust concentration, and the amount of generated indoor air pollutants.

According to still another embodiment of the present disclosure, there is provided a system for achieving carbon neutrality. The system includes an energy information acquisition device that acquires energy information, and an apparatus for achieving carbon neutrality that quantitatively measures and evaluates ESG achievement rates by receiving the energy information from the energy information acquisition device. The apparatus for achieving the carbon neutrality analyzes energy performance of factories, industrial facilities, and plants, derives energy saving factors and renewable energy production factors, verifies performance of facility materials and facility construction methods, optimizes internal air, and quantitatively measures and evaluates environmental, social, and governance (ESG) achievement rates for the factories, the industrial facilities, and the plants. In addition, deriving the energy saving factors and the renewable energy production factors may include performing energy modeling by reflecting information including at least one or a combination of shape information, weather information, insulation and heat generation information, facility information, facility efficiency information, and facility operation information of the factories, the industrial facilities, and the plants, and analyzing at least one or a combination of energy consumption, carbon emissions, and heat circulation of the factories, the industrial facilities, and the plants, through energy simulation. In addition, deriving the energy saving factors and the renewable energy production factors may include deriving passive technology elements or active technology elements which are energy-saving elements, through machine learning-based energy optimization models and data mining. In addition, optimizing the internal air may include constructing and providing a factory energy management system (FEMS) for energy optimization by reflecting results of analyzing the energy performance of the factories, industrial facilities, and the plants. In addition, optimizing the internal air may include controlling an IoT-based ventilation device through a test bed to which the facility materials and the facility construction methods are applied, and performing a simulation for optimizing indoor air by collecting information from an IoT-based sensor installed in the test bed, and providing settings for an IoT-based ventilation system that optimizes the indoor air in a prescribed space, based on results of the simulation. In addition, quantitatively measuring and evaluating the ESG achievement rates may include calculating a carbon reduction amount by applying a carbon emission factor, based on data collected from a FEMS or a ventilation system installed in the factories, the industrial facilities, and the plants, and evaluating ESG evaluation indicators for greenhouse gas emissions, an energy usage amount, a renewable energy usage ratio, a waste discharge amount, a water usage amount, air pollutant emissions, indoor fine dust concentration, and the amount of generated indoor air pollutants.

According to the embodiments of the present specification, guidelines for securing energy performance for rapid decision-making from an early stage of design of the industrial sites including the factories, the industrial facilities, and the plants are suggested. In this manner, the industrial sites can be established to minimize energy consumption and maximize energy efficiency by applying the passive design technology elements and the active system technology elements, and systematic and integrated carbon-neutral solutions can be provided through independent energy production. In addition, materials and construction methods for forming the industrial sites are applied, and ventilation systems are applied to establish a pleasant industrial environment. Therefore, quality of industrial safety and industrial health can be ensured.

### BRIEF DESCRIPTION OF THE DRAWINGS

The accompanying drawings, which are included to provide a further understanding of the present disclosure and constitute a part of the detailed description, illustrate embodiments of the present disclosure and serve to explain technical features of the present disclosure together with the description.

FIG. 1 is a block diagram illustrating a system for achieving carbon neutrality according to an embodiment of the present disclosure.

FIG. 2 is a conceptual diagram for describing the system for achieving carbon neutrality according to the embodiment of the present disclosure.

FIG. 3 is a flow chart illustrating a method for achieving carbon neutrality according to another embodiment of the present disclosure.

FIG. 4 is a block diagram illustrating an apparatus for achieving carbon neutrality according to still another embodiment of the present disclosure.

### DETAILED DESCRIPTION

Hereinafter, embodiments of the present specification will be specifically described with reference to the drawings. However, detailed description will be omitted with regard to well-known functions or configurations which may obscure the concept of the embodiments in the following description and the accompanying drawings. In addition, throughout the specification, the term “including” a certain component does not exclude other components unless specifically stated otherwise, and means that other components may be further included.

In addition, while the terms indicating a first component, a second component, and the like may be used to describe various components, the components should not be limited by the terms. The terms may be used to distinguish one component from another component. For example, without departing from the scope of the present specification, a first component may be referred to as a second component, and similarly, the second component may be referred to as the first component.

The terms used in the present specification are used only to describe a specific embodiment, and are not intended to limit the present specification. Expression for a singular component includes expression for a plurality of components unless the context clearly indicates otherwise. In the present application, the terms “includes”, “is provided with”, and the like are intended to specify the presence of a feature, a number, a step, an operation, a component, a part, or a combination thereof which are described in the present specification, and it should be understood that the terms do not exclude in advance a possibility of the presence or additions of one or more other features, numbers, steps, operations, components, parts, or combinations thereof.

Unless specifically defined otherwise, all terms used herein, which include technical or scientific terms, have the same meaning as those which are commonly understood by a person skilled in the art to which the present specification pertains. The terms such as those defined in commonly used dictionaries should be interpreted as having meanings consistent with the meanings in the context of the related art, and are not interpreted in an idealistic or overly formal sense unless explicitly defined herein.

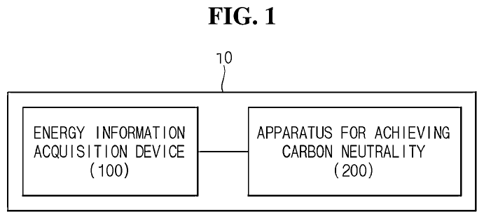

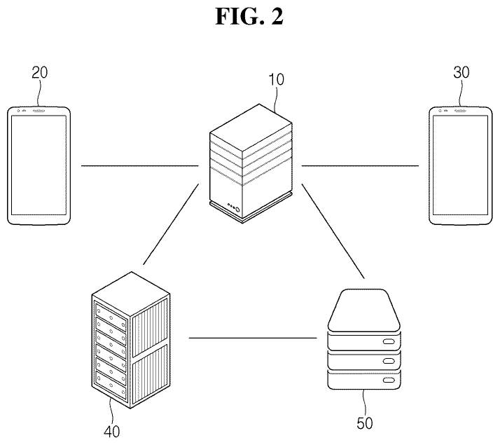

FIG. 1 is a block diagram illustrating a system for achieving carbon neutrality according to an embodiment of the present disclosure. FIG. 2 is a conceptual diagram for describing the system for achieving carbon neutrality according to the embodiment of the present disclosure.

Referring to FIG. 1, a system for achieving carbon neutrality (10) according to an embodiment of the present disclosure may include an energy information acquisition device (100) and an apparatus for achieving carbon neutrality (200).

The energy information acquisition device (100) may acquire energy information from an energy management system provided in factories, industrial facilities, and plants. In this case, the energy information may include power, a flow rate, a gas, a temperature, a humidity, a pressure, and weather data of the factories, the industrial facilities, and the plants. The energy information acquisition device (100) may transmit the energy information to the apparatus for achieving carbon neutrality (200).

The apparatus for achieving carbon neutrality (200) may receive the energy information from the energy information acquisition device (100). Thereafter, the apparatus for achieving carbon neutrality (200) analyzes energy performance of the factories, the industrial facilities, and the plants, derives energy saving factors and renewable energy production factors, verifies performance of facility materials and facility construction methods, for example, to comply with Global Reporting Initiative (GRI) standards as international standards, optimizes internal air in accordance with the GRI standards, and quantitatively measures and evaluates environmental, social, and governance ESG) achievement rates for the factories, the industrial facilities, and the plants. In addition, the system for achieving carbon neutrality (10) to be described below with reference to FIG. 2 may quantitatively measure and evaluate the environmental, social, and governance (ESG) achievement rates for the factories, the industrial facilities, and the plants, through a plurality of devices connected to the system for achieving carbon neutrality (10).

Referring to FIG. 2, the system for achieving carbon neutrality (10) according to the embodiment of the present disclosure may include a consultant terminal (20) serving as a first terminal, an administrator terminal (30) serving as a second terminal, a factory energy management system (FEMS, 40), and a big data server (50), and the respective devices may communicate with each other by being connected to a network.

The network described in the present disclosure may be a core network integrated with a wired public network, a wireless mobile communication network, or a portable Internet, or may mean a global open computer network structure that provides various services existing in Transmission Control Protocol (TCP/IP protocol), User Datagram Protocol (UDP), and an upper hierarchy thereof, that is, Hyper Text Transfer Protocol (HTTP), Hyper Text Transfer Protocol Secure (HTTPS), Telnet, File Transfer Protocol (FTP), Domain Name System (DNS), Simple Mail Transfer Protocol (SMTP), Message Queueing Telemetry Transport (MQTT) Protocol, Inter Planetary File System (IPFS), and the like, and may comprehensively mean a data communication network which can transmit and receive data in various forms without being limited to these examples.

The terminal in the present disclosure should be interpreted as including various communication means such as a desktop, a tablet, a netbook, a personal digital assistant (PDA), a portable multimedia player (PMP), a smartphone, and a wearable smart device, and may fulfill various functions provided by a server through web-based or separate software/applications.

The consultant terminal (20) in the present disclosure may have access to the system for achieving carbon neutrality (10), may monitor and review processes of performing energy optimization and internal air optimization which are performed by the system for achieving carbon neutrality (10) in the factories, the industrial facilities, and the plants, and may correct the processes through an interface provided when necessary.

The system for achieving carbon neutrality (10) in the present disclosure may analyze energy performance of the factories, the industrial facilities, and the plants, may derive energy saving factors and renewable energy production factors, may evaluate hazardous substances in indoor building materials, may verify performance of facility materials and facility construction methods, may perform control on energy use in the factories, the industrial facilities, and the plants, may optimize internal air, may perform monitoring and optimization analysis, and may quantitatively measure and evaluate environmental, social, and governance (ESG) achievement rates for the factories, the industrial facilities, and the plants.

The administrator terminal (30) in the present disclosure may register requirements and design information of a building owner, such as carbon neutrality, zero-energy building realization, eco-friendly certification acquisition, and ESG management, in the system for achieving carbon neutrality (10), may search, confirm, and output design drawings, construction drawings, material lists, installation information, and FEMS configuration information to which technical elements for achieving carbon neutrality provided by the system for achieving carbon neutrality (10) are applied, and may reflect the information in design, site construction, and an operation stage of buildings including the factories.

The FEMS (40) in the present disclosure may be an Internet-of-Things (IoT)-based energy optimization system in which measurement, control, management, and operation are integrated to provide an optimized energy management plan by monitoring an energy usage history to achieve comfortable indoor environment maintenance and efficient energy management in the factories, the industrial facilities, and the plants.

The FEMS (40) is an energy management system that optimizes energy supplied and consumed in the factories through monitoring, analysis, planning, and control in measuring the energy in facilities inside the factories. The FEMS (40) is conceptually similar to BEMS, except that an application target is changed from buildings to factories. However, unlike the buildings, management of various production facilities is essential depending on characteristics of the factories. Therefore, the FEMS (40) is different from the BEMS in that understanding and experiences in the facilities are important, and real-time control of the production facilities is important.

The big data server (50) in the present disclosure may collect data from the FEMS (40) installed in the factories, the industrial facilities, and the plants, an IoT-based ventilation system, and an IoT-based test bed built for indoor air performance tests, and may perform data preprocessing, analysis, and visualization. The data managed by the big data server (50) may be utilized for artificial intelligence (AI)-based energy management and indoor air optimization model learning, energy efficiency analysis, and indoor air performance evaluation. In addition, the big data server (50) may be built as an independent data server, or may be included in the system for achieving carbon neutrality (10).

The server described in the present disclosure may be built as a server that plays at least one of roles of a web server, a database server, a cloud server, an IoT-based server, and a mobile server. For example, processed results may be displayed on a web page through a network, or required input data may be transmitted through the web page. Here, the web page should be interpreted as including software for performing specific tasks such as web applications in addition to simple texts, images, sounds, and videos, and may be constructed to provide applications and interfaces installed on a desktop, a laptops, a smartphone, a tablet PC, and the like. In addition, the server may perform at least one of functions of a web application server, a web server, a cloud server, an IoT-based server, a mobile server, and a database server, in one physical server, or a plurality of physically separated servers may be configured and operated. However, the server is not limited thereto, and a type of the server may be changed in various ways at a level which is obvious to a person skilled in the art.

Hereinafter, specific items relating to the system for achieving carbon neutrality (10) will be described.

The system for achieving carbon neutrality (10) may manage a process by dividing the process into a carbon neutrality/zero-energy optimization stage, an internal air optimization stage, and an ESG achievement rate evaluation stage, and may fulfil functions in each stage.

The system for achieving carbon neutrality (10) may analyze the energy performance of the factories, the industrial facilities and the plants, may derive the energy saving factors and the renewable energy production factors, and may assist a procedure in each certification step for acquiring certification in the factories, the industrial facilities, and the plants.

The system for achieving carbon neutrality (10) may perform energy modeling, based on an ESG platform to which the factory energy management system (FEMS) is applied by reflecting information including at least one or a combination of shape information, weather information, insulation and heat generation information, facility information, facility efficiency information, and facility operation information of the factories, the industrial facilities, and the plants, and may analyze at least one or a combination of energy consumption, carbon emissions, and heat circulation in the factories, the industrial facilities, and the plants, through energy simulation. Here, the factory energy management system (FEMS) is an integrated system that monitors, measures, analyzes, and optimizes energy consumption on a real-time basis in the factories or the industrial plants. The FEMS is an advanced energy management solution in which usage amounts of various energy sources such as electricity, gas, and water are traced, energy efficiency of production processes and facilities is improved, an energy consumption pattern is identified by utilizing a predictive analysis and an artificial intelligence technology, and an optimal operation strategy is established to reduce overall energy costs, reduce carbon emissions, and build a sustainable production system.

The system for achieving carbon neutrality (10) may perform Building Information Modeling (BIM) by reflecting design data including shape information or the like of the factories, the industrial facilities, and the plants, which is received from the administrator terminal (30), may extract weather data of an area where the factories, the industrial facilities, and the plants are located, may perform energy simulation, and may analyze, quantify, and visualize thermal comfort for determining whether the energy simulation satisfies an energy usage amount, energy costs, carbon emissions, and a thermal comfort range of employees.

The Building Information Modeling (BIM) is a technology for generating one or more accurate virtual models of the factories and the plants by using a digital method, and includes all data required for assisting design, construction, procurement activities, or the like required for design, construction, and operation during a life cycle of the building.

The system for achieving carbon neutrality (10) may derive passive technology elements or active technology elements which are energy-saving elements, by applying at least one of a machine learning-based energy optimization model and a data mining technique, and may verify an energy-saving effect by performing a simulation when the technology elements are applied to the factories, the industrial equipment, and the plants. For example, the system for achieving carbon neutrality (10) may derive the passive and active technology elements by applying a BIM-based data mining decision-making algorithm modeled by analyzing BIM-based data managed by the big data server (50) and energy usage amount data collected from the FEMS (40) and the IoT-based ventilation system. Here, as an example, LSTM-AutoEncorder may be used as machine learning. As the data mining, various types of known algorithms may be used alone or in combination, such as algorithms including a decision trees, naive Bayes, and a support vector machine (SVM) which are suitable for classification for dividing data into predefined categories, and algorithms including K-means, hierarchical clustering, and DBSCAN which are suitable for clustering for grouping data having similar characteristics.

In addition, the passive and active technology elements of the factories, the industrial equipment, and the plants can be predicted through a machine learning-based energy optimization model trained by using energy usage amount data collected from the FEMS (40) and the IoT-based ventilation system which are managed by the big data server (50).

The passive technology described above is a technology in which energy is ‘conserved’ and ‘saved’ by utilizing insulation performance and a form of a factory structure instead of a mechanical heating and cooling system, includes a high-insulation window technology, a high-efficiency insulation material technology, and a high-efficiency heat exchange ventilation technology. The active technology means a renewable energy production technology such as wind power, solar power, and solar energy which change the factory itself from an energy consuming space to an energy producing space.

The system for achieving carbon neutrality (10) may provide analysis results obtained by simulating BIM information reflecting the derived technical elements and the energy usage amount, to the consultant terminal (20).

The consultant terminal (20) may directly register, change, and delete allocations, settings, capacity, and the like of energy saving factors of the BIM through a user interface provided by the system for achieving carbon neutrality (10), and may confirm energy analysis results by reflecting the changed information and performing the simulation.

The system for achieving carbon neutrality (10) may provide the factory energy management system (FEMS) for energy optimization by reflecting results of analyzing the energy performance of the factories, the industrial facilities, and the plants. For example, the factory energy management system (FEMS) may be configured as a comprehensive energy management solution for reducing overall energy costs and achieving a sustainability goal. In the comprehensive energy management solution, for energy optimization, a real-time energy consumption data collection sensor, an IoT device, a big data processing and analysis platform, an AI-based prediction and optimization algorithm, a dashboard, and a report generation tool are integrated to monitor and analyze energy usage patterns of the factories, energy efficiency of production processes and facilities is improved, peak power management and a demand response are optimized, integration of renewable energy is facilitated, and carbon emissions are automatically calculated to assist ESG reporting.

The system for achieving carbon neutrality (10) may correct all related design and construction information by reflecting the analyzed and simulated energy performance analysis results so that the results can be applied to design and construction, and may configure and provide the IoT-based FEMS (40) for comfortable indoor environment maintenance and efficient energy management in the factories and the plants.

For example, the system for achieving carbon neutrality (10) may configure a measuring device such as a power meter, a flow meter, temperature, humidity, and illuminance sensors, and a control device for lighting, a boiler, an air conditioners, a heater, and a gas which are required depending on a shape, a space size, and a type of facilities of proposed factories and plants, and may provide the measuring device and the control device by automatically setting facility operation information, a monitoring plan, and an IoT-based data collection plan for optimal energy management.

In addition, the system for achieving carbon neutrality (10) may derive and apply the configuration and setting information of the FEMS (400) through an energy optimization algorithm trained from operation data of the FEMS (40) managed by the big data server (50).

In addition, a user interface may be provided so that the consultant terminal (20) may customize the configuration of the automatically provided FEMS (40).

The system for achieving carbon neutrality (10) may provide a certification procedure for acquiring eco-friendly building certification, and may manage at least one information out of a schedule, an evaluation item, an evaluation standard, a submission document, an evaluation document, and a report which are required for each certification stage.

For example, an administrator may select a desired eco-friendly building certification list through the administrator terminal (30), may register information required for acquiring certification, such as a building's usage, a certification purpose, and design information, and may request for certification. In this case, the system for achieving carbon neutrality (10) may generate a certification process for the request. Thereafter, the consultant terminal (20) may confirm a command for a certification procedure, certification item evaluation, report writing, and the like which are to be performed in accordance with the certification procedure generated by the system for achieving carbon neutrality (10), and may follow the command through the provided interface.

The system for achieving carbon neutrality (10) may evaluate hazardous substances in indoor building materials, and may calculate an eco-friendly material level of the indoor building materials.

For example, the system for achieving carbon neutrality (10) may measure emission of hazardous substances such as volatile organic compounds, formaldehyde, or the like generated from each material, and may measure exposure concentration of the hazardous substances in a standard model room in which a size and a ventilation condition are prescribed to determine concentration of indoor pollutants of the material. In this case, the exposure concentration of the hazardous substances in the standard model room may be predicted through a correlation formula with the emission of the hazardous substances per unit area of the product, an area or a quantity of the product applied to the standard model room, the number of ventilation cycles (times/h) of the standard model room, and a volume of the standard model room. The eco-friendly material level corresponding to a range in which a predicted value exists may be calculated by comparing the predicted value with a range value of a predefined eco-friendly material level.

The system for achieving carbon neutrality (10) may perform an indoor air analysis and a simulation by applying IoT-based monitoring or a control technology through the test bed built by applying the facility materials and the facility construction methods.

The system for achieving carbon neutrality (10) may collect information of a sensor installed in the IoT-based test bed, may control the IoT-based ventilation device installed in the test bed, and may collect and analyze indoor air data for a specific environment.

In this case, a mock-up of a specific space to which eco-friendly indoor building materials and eco-friendly facility construction methods are applied is configured in the test bed, and IoT-based sensors for measuring the concentration of indoor hazardous substances such as formaldehyde and volatile organic compounds, and fine dust, and the IoT-based ventilation device are installed. The reason is to measure how indoor air is affected by indoor building materials, construction methods, and ventilation systems which affect the indoor air.

In addition, the system for achieving carbon neutrality (10) may generate external environmental factors such as an inflow of fine dust in the atmosphere and seasonal weather conditions, as virtual data, and may assist applications when the simulation is performed.

In addition, the system for achieving carbon neutrality (10) may provide a user interface for controlling the ventilation system installed in the test bed and monitoring indoor air conditions of the test bed, and may assist the consultant terminal (20) to perform various simulations for indoor air optimization through the provided user interface. Here, as an example, an air level for the indoor air optimization may follow on-site safety standards presented by the Ministry of Health.

The system for achieving carbon neutrality (10) may collect data on a real-time basis from various sensors and control devices which are installed in the test bed, may store and manage the data in the big data server (50), and may instruct to perform data purification, analysis, and visualization.

The data collected from the test bed may include a type of the eco-friendly indoor building materials, the eco-friendly facility construction methods, the amount of the generated hazardous substances, building structure information, indoor temperature and humidity, an air flow, the amount of inflow air, fine dust concentration, and the like.

The system for achieving carbon neutrality (10) may provide settings for the IoT-based ventilation system that optimizes the indoor air in a prescribed space, based on indoor air analysis results collected from the simulation performed in the test bed.

More specifically, the system for achieving carbon neutrality (10) may remove a minimum amount of the hazardous substances generated even by applying the eco-friendly materials and the eco-friendly facility construction methods, and may provide a ventilation system and optimized settings which maintain indoor optimal air conditions by filtering out pollutants flowing in from the outside.

For example, in addition to basic device components of the IoT-based ventilation system, a type, the number, and installation locations of devices, and operating and stopping conditions, an order, and the like of the ventilation device for a specific indoor conditions, which depend on processing capacity for maintaining optimal indoor air in accordance with a shape, a space size, and internal and external factors of the factories and the plants may be derived through a machine learning optimization algorithm. In addition, a user interface may be provided so that the consultant terminal (20) can customize the derived results.

The system for achieving carbon neutrality (10) may quantitatively measure, evaluate, and provide the ESG achievement rates for the factories, the industrial facilities, and the plants.

The system for achieving carbon neutrality (10) may calculate the amount of carbon reduction by applying carbon emission factors, based on the analyzed energy performance of the factories, the industrial facilities, and the plants, the derived energy saving factors, and the renewable energy production factors, or various types of operation data such as processes, transportation, environment, waste, and the like in the factories, the industrial facilities, and the plants or business places, which are provided by the FEMS (40). In this case, the carbon emission factor may be calculated by applying each fuel emission factor based on Table 1 presented by the Intergovernmental Panel on Climate Change (IPCC).

TABLE 1

| | | | Carbon Emission Factor | | |
|---|---|---|---|---|---|
| | | | kg | * (ton | (TJ/10³ |
| Fuel Classification | | | C/GJ | C/toe) | TON) |
| Liquid | Primary | Crude Oil | 20 | 0.829 | — |
| Fossil Fuel | Fuel | Liquefied | 17.2 | 0.63 | — |
| | | Natural Gas | | | |
| | | (LNG) | | | |
| | Sec- | Gasoline | 18.9 | 0.783 | 44.8 |
| | ondary | Aviation | 18.9 | 0.783 | 44.59 |
| | Fuel | Gasoline | | | |
| | | Kerosene | 19.6 | 0.812 | 44.75 |
| | | Air Fuel | 19.5 | 0.808 | — |
| | | Diesel | 20.2 | 0.837 | 43.33 |
| | | Heavy Oil | 21.1 | 0.875 | 40.19 |
| | | LPG | 17.2 | 0.713 | 47.31 |
| | | Naphtha | (20.00)(a) | 0.829 | 45.01 |
| | | Asphalt | 22 | 0.912 | 40.19 |
| | | (Bitumen) | | | |
| | | Lubricant | (20.00)(a) | 0.829 | 40.19 |
| | | Petroleum | 27.5 | 1.14 | 31 |
| | | Coke | | | |
| | | Refinery | (20.00)(a) | 0.829 | 44.8 |
| | | Feedstock | | | |
| Solid Fossil | Primary | Anthracite | 26.8 | 1.1 | |
| Fuel | Fuel | Coal for Coke | 25.8 | 1.059 | |
| Secondary | | Fuel Coal | 25.8 | 1.059 | |
| Fuel | | Brown Coal | 27.6 | 1.132 | |
| | | Peat | 28.9 | 1.186 | |
| | | BKB & Patent | (25.80)(a) | 1.059 | |
| | | Fuel | | | |
| | | Coke Oven/ | 29.5 | 1.21 | |
| | | Gas Coke | | | |
| | | Coke Oven | 13.0(b) | | |
| | | Gas | | | |
| | | Blast Furnace | 66.0(b) | | |
| | | Gas | | | |

| | | | |
|---|---|---|---|
| Gas Fossil Fuel | LNG (dry) | 15.3 | 0.637 |
| Biomass | Solid Biomass | 29.9 | 1.252 |
| (Excluded When CO₂ | Liquid | (20.00)(a) | 0.837 |
| emissions are | Biomass | | |
| calculated) | Gas Biomass | (30.60)(a) | 1.281 |

In addition, for example, a standard for carbon emission factors may follow the Global Reporting Initiative (GRI) standards.

The system for achieving carbon neutrality (10) may manage ESG evaluation indicators, may analyze IoT-based data collected from the FEMS (40) or the ventilation system installed in the factories, the industrial facilities, and the plants, and may evaluate the ESG evaluation indicators for at least one of the greenhouse gas emissions, the energy usage amount, the renewable energy usage ratio, the waste discharge amount, the water usage amount, the air pollutant emissions, the indoor fine dust concentration, and the amount of generated indoor air pollutants.

The data collected from the EMS (40) or the IoT-based ventilation system installed in the factories, the industrial facilities, and the plants may be stored in the big data server (50), and numerical and statistical work can be performed on the ESG evaluation indicators through data preprocessing and data analysis by ESG evaluation indicators.

In addition, the collected data may be expressed as texts, tables, and visualized materials, and may be provided in various forms such as web screens, electronic documents, Excel, and reports.

For example, the present disclosure can accept and apply real-time ESG monitoring and a periodic unit reporting function which accept GRI standards as ESG international standards [GRI-201 (Economic Performance), -205 (Anti-corruption), -301 (Materials), -302 (Energy), -303 (Water and Effluents), -304 (Biodiversity), -305 (Emissions), -306 (Effluents and Waste), -308 (Supplier Environmental Assessment), -402 (Labor), -411 (Rights of Indigenous Peoples), -413 (Local Communities), -414 (Supplier Social Assessment), -416 (Customer Health and Safety)]. In addition, measurement and evaluation may be performed through the present disclosure by applying selection evaluation of ESG Certification Report standards (AA1000AP, AA1000AS, and the like).

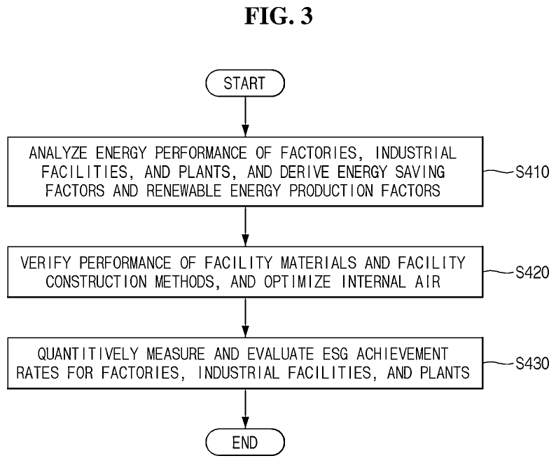

FIG. 3 is a flow chart illustrating a method for achieving carbon neutrality according to another embodiment of the present disclosure.

Referring to FIG. 3, the apparatus for achieving carbon neutrality may analyze the energy performance of the factories, the industrial facilities, and the plants, and may derive the energy saving factors and the renewable energy production factors (S410). The apparatus for achieving carbon neutrality (for example, the apparatus for achieving carbon neutrality (200) in FIG. 1) may receive the energy information from an energy information acquisition device (for example, the energy information acquisition device (100) in FIG. 1). In addition, the apparatus for achieving carbon neutrality may receive data including the energy information from a separate device and server (for example, the consultant terminal (20) serving as the first terminal, the manager terminal (30) serving as the second terminal, the factory energy management system (FEMS) 40, and the big data server (50)) connected to the apparatus for achieving carbon neutrality).

The apparatus for achieving carbon neutrality may perform energy modeling by reflecting information including at least one or a combination of shape information, weather information, insulation and heat generation information, facility information, facility efficiency information, and facility operation information of the factories, the industrial facilities, and the plants, and may analyze at least one or a combination of energy consumption, carbon emissions, and heat circulation of the factories, the industrial facilities, and the plants, through energy simulation.

The apparatus for achieving carbon neutrality may derive passive technology elements or active technology elements, which are energy-saving elements, through a machine learning-based energy optimization model and data mining.

The apparatus for achieving carbon neutrality may verify performance of facility materials and facility construction methods, and may optimize internal air (S430). The apparatus for achieving carbon neutrality may configure and provide the factory energy management system (FEMS) for energy optimization by reflecting results of analyzing the energy performance of the factories, the industrial facilities, and the plants.

The apparatus for achieving carbon neutrality may control the IoT-based ventilation device through the test bed to which the facility materials and the facility construction methods are applied. In this manner, the apparatus for achieving carbon neutrality may collect information from the IoT-based sensor installed in the test bed to perform a simulation for optimizing indoor air, and may provide settings for the IoT-based ventilation system that optimizes indoor air in a prescribed space, based on results of the simulation.

The apparatus for achieving carbon neutrality may quantitatively measure and evaluate the environmental, social, and governance (ESG) achievement rates for the factories, the industrial facilities, and the plants (S450). The apparatus for achieving carbon neutrality may calculate a carbon reduction amount by applying a carbon emission factor, based on data collected from the FEMS or the ventilation system installed in the factories, the industrial facilities, and the plants, and may evaluate ESG evaluation indicators for the greenhouse gas emissions, the energy usage amount, the renewable energy usage ratio, the waste discharge amount, the water usage amount, the air pollutant emissions, the indoor fine dust concentration, and the amount of generated indoor air pollutants.

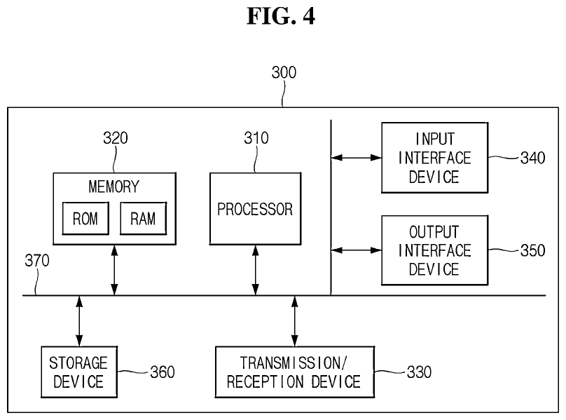

FIG. 4 is a block diagram illustrating an apparatus for achieving carbon neutrality according to still another embodiment of the present disclosure.

An apparatus for achieving carbon neutrality (300) in FIG. 4 may be the same as the apparatus for achieving carbon neutrality (200) in FIG. 1. The apparatus for achieving carbon neutrality (300) may include at least one processor (310), a memory (320), and a transmission/reception device (330) connected to a network to perform communication. In addition, the apparatus for achieving carbon neutrality (300) may further include an input interface device (340), an output interface device (350), a storage device (360), and the like. The respective components included in the apparatus for achieving carbon neutrality (300) may be connected by a bus (370) to perform communication with each other. However, the respective components included in the apparatus for achieving carbon neutrality (300) may be connected through an individual interface or an individual bus by mainly using the processor (310), instead of a common bus (370). For example, the processor (310) may be connected to at least one of the memory (320), the transmission/reception device (330), the input interface device (340), the output interface device (350), and the storage device (360) through a dedicated interface.

The processor (310) may execute a program command stored in at least one of the memory (320) and the storage device (360). The processor (310) may mean a central processing unit (CPU), a graphics processing unit (GPU), or a dedicated processor for executing methods according to the embodiments of the present disclosure. Each of the memory (320) and the storage device (360) may include at least one of a volatile storage medium and a non-volatile storage medium. For example, the memory (320) may include at least one of a read only memory (ROM) and a random access memory (RAM).

Most of the terms used in the present disclosure are selected from those commonly used in the field, but some terms are arbitrarily selected by the applicant, and the meanings are described in detail in the following description when needed. Therefore, the present disclosure should be understood, based on the intended meaning of the terms, instead of simple names or meanings of the terms.

It will be apparent to those skilled in the art that the present disclosure may be embodied in other specific forms within the scope not departing from the essential characteristics of the present disclosure. Therefore, the detailed description should not be interpreted as restrictive description in all respects, and should be considered as exemplary description. The scope of the present disclosure should be determined by reasonable interpretation of the appended claims, and all modifications within the equivalent scope of the present disclosure are intended to be included within the scope of the present disclosure.

What is claimed is:

1. A method for achieving carbon neutrality, comprising:
analyzing energy performance of factories, industrial facilities, and plants, and deriving energy saving factors and renewable energy production factors;
verifying performance of facility materials and facility construction methods, and optimizing internal air; and
quantitatively measuring and evaluating environmental, social, and governance (ESG) achievement rates of the factories, the industrial facilities, and the plants.

2. The method of claim 1,
wherein deriving the energy saving factors and the renewable energy production factors includes performing energy modeling by reflecting information including at least one or a combination of shape information, weather information, insulation and heat generation information, facility information, facility efficiency information, and facility operation information of the factories, the industrial facilities, and the plants, and analyzing at least one or a combination of energy consumption, carbon emissions, and heat circulation of the factories, the industrial facilities, and the plants through energy simulation.

3. The method of claim 1,
wherein deriving the energy saving factors and the renewable energy production factors includes deriving passive technology elements or active technology elements which are energy-saving elements, through machine learning-based energy optimization models and data mining.

4. The method of claim 1,
wherein optimizing the internal air includes constructing and providing a factory energy management system (FEMS) for energy optimization by reflecting results of analyzing the energy performance of the factories, industrial facilities, and the plants.

5. The method of claim 1,
wherein optimizing the internal air includes controlling an IoT-based ventilation device through a test bed to which the facility materials and the facility construction methods are applied, and performing a simulation for optimizing indoor air by collecting information from an IoT-based sensor installed in the test bed, and providing settings for an IoT-based ventilation system that optimizes the indoor air in a prescribed space, based on results of the simulation.

6. The method of claim 1,
wherein quantitatively measuring and evaluating the ESG achievement rates include calculating a carbon reduction amount by applying a carbon emission factor, based on data collected from a FEMS or a ventilation system installed in the factories, the industrial facilities, and the plants, and evaluating ESG evaluation indicators for greenhouse gas emissions, energy consumption, a renewable energy usage ratio, waste emissions, water consumption, air pollutant emissions, indoor fine dust concentration, and indoor air pollutant generation.

7. An apparatus for achieving carbon neutrality, comprising:
a processor;
a memory in which one or more instructions executed by the processor are stored,
wherein the one or more instructions include analyzing energy performance of factories, industrial facilities, and plants, and deriving energy saving factors and renewable energy production factors, verifying performance of facility materials and facility construction methods, and optimizing internal air, and quantitatively measuring and evaluating environmental, social, and governance (ESG) achievement rates of the factories, the industrial facilities, and the plants.

8. The apparatus of claim 7,
wherein deriving the energy saving factors and the renewable energy production factors includes performing energy modeling by reflecting information including at least one or a combination of shape information, weather information, insulation and heat generation information, facility information, facility efficiency information, and facility operation information of the factories, the industrial facilities, and the plants, and analyzing at least one or a combination of energy consumption, carbon emissions, and heat circulation of the factories, the industrial facilities, and the plants through energy simulation.

9. The apparatus of claim 7,
wherein deriving the energy saving factors and the renewable energy production factors includes deriving passive technology elements or active technology elements which are energy-saving elements, through machine learning-based energy optimization models and data mining.

10. The apparatus of claim 7,
wherein optimizing the internal air includes configuring and providing a factory energy management system (FEMS) for energy optimization by reflecting results of analyzing the energy performance of the factories, industrial facilities, and the plants.

11. The apparatus of claim 7,
wherein optimizing the internal air includes controlling an IoT-based ventilation device through a test bed to which the facility materials and the facility construction methods are applied, and performing a simulation for optimizing indoor air by collecting information from an IoT-based sensor installed in the test bed, and providing settings for an IoT-based ventilation system that optimizes the indoor air in a prescribed space, based on results of the simulation.

12. The apparatus of claim 7,
wherein quantitatively measuring and evaluating the ESG achievement rates include calculating a carbon reduction amount by applying a carbon emission factor, based on data collected from a FEMS or a ventilation system installed in the factories, the industrial facilities, and the plants, and evaluating ESG evaluation indicators for greenhouse gas emissions, energy consumption, a renewable energy usage ratio, waste emissions, water consumption, air pollutant emissions, indoor fine dust concentration, and indoor air pollutant generation.

13. A system for achieving carbon neutrality, comprising:
an energy information acquisition device that acquires energy information; and
an apparatus for achieving carbon neutrality that quantitatively measures and evaluates ESG achievement rates by receiving the energy information from the energy information acquisition device,
wherein the apparatus for achieving the carbon neutrality analyzes energy performance of factories, industrial facilities, and plants, derives energy saving factors and renewable energy production factors, verifies performance of facility materials and facility construction methods, optimizes internal air, and quantitatively measures and evaluates environmental, social, and governance (ESG) achievement rates of the factories, the industrial facilities, and the plants.

14. The system of claim 13,
wherein deriving the energy saving factors and the renewable energy production factors includes performing energy modeling by reflecting information including at least one or a combination of shape information, weather information, insulation and heat generation information, facility information, facility efficiency information, and facility operation information of the factories, the industrial facilities, and the plants, and analyzing at least one or a combination of energy consumption, carbon emissions, and heat circulation of the factories, the industrial facilities, and the plants through energy simulation.

15. The system of claim 13,
wherein deriving the energy saving factors and the renewable energy production factors includes deriving passive technology elements or active technology elements which are energy-saving elements, through machine learning-based energy optimization models and data mining.

16. The system of claim 13,
wherein optimizing the internal air includes constructing and providing a factory energy management system (FEMS) for energy optimization by reflecting results of analyzing the energy performance of the factories, industrial facilities, and the plants.

17. The system of claim 13,
wherein optimizing the internal air includes controlling an IoT-based ventilation device through a test bed to which the facility materials and the facility construction methods are applied, and performing a simulation for optimizing indoor air by collecting information from an IoT-based sensor installed in the test bed, and providing settings for an IoT-based ventilation system that optimizes the indoor air in a prescribed space, based on results of the simulation.

18. The system of claim 13,
wherein quantitatively measuring and evaluating the ESG achievement rates include calculating a carbon reduction amount by applying a carbon emission factor, based on data collected from a FEMS or a ventilation system installed in the factories, the industrial facilities, and the plants, and evaluating ESG evaluation indicators for greenhouse gas emissions, energy consumption, a renewable energy usage ratio, waste emissions, water consumption, air pollutant emissions, indoor fine dust concentration, and indoor air pollutant generation.
